(19) United States
(12) Patent Application Publication
(10) Pub. No.: US 2010/0254088 A1
(43) Pub. Date: Oct. 7, 2010

(54) HEAT TRANSPORT DEVICE, ELECTRONIC APPARATUS, AND HEAT TRANSPORT DEVICE MANUFACTURING METHOD

(75) Inventors: Yuichi Ishida, Kanagawa (JP); Mitsuo Hashimoto, Kanagawa (JP); Kazuaki Yazawa, Kanagawa (JP); Hiroyuki Ryoson, Kanagawa (JP); Tatsuhiko Shigemoto, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/730,593

(22) Filed: Mar. 24, 2010

(30) Foreign Application Priority Data
Apr. 3, 2009 (JP) 2009-091216

(51) Int. Cl. H05K 7/20; F28D 15/00; B21D 53/02

(52) U.S. Cl. 361/700; 165/104.21; 29/890.03

(57) ABSTRACT

According to an embodiment of the present invention, there is provided a heat transport device including a working fluid, an evaporation portion, a condenser portion, a flow path portion, and an area. The working fluid includes pure water and an organic compound bearing a hydroxyl group. The evaporation portion causes the working fluid to evaporate from a liquid phase to a vapor phase. The condenser portion communicates with the evaporation portion, and causes the working fluid to condense from the vapor phase to the liquid phase. The flow path portion causes the working fluid condensed in the condenser portion to the liquid phase to flow to the evaporation portion. The area is made of a carbon material and provided on at least one of the evaporation portion, the condenser portion, and the flow path portion.

### BACKGROUND OF THE INVENTION

1. Field of the Invention

The present invention relates to a heat transport device thermally connected to a heat source of an electronic apparatus, an electronic apparatus including the heat transport device, and a heat transport device manufacturing method.

2. Description of the Related Art

A heat transport device such as a heat spreader, a heat pipe, or a CPL (Capillary Pumped Loop) has been used as a device thermally connected to a heat source of an electronic apparatus, such as a CPU (Central Processing Unit) of a PC (Personal Computer), to absorb and diffuse heat of the heat source. For example, a solid-type metal heat transport device made of for example a copper plate is known, and a heat transport device including a working fluid has been proposed recently.

It is known that carbon materials such as carbon nanotube are high in thermal conductivity and contribute to acceleration of evaporation. As a heat transport device using carbon nanotube, a heat pipe is known (see, for example, U.S. Pat. No. 7,213,637; column 3, line 66 to column 4, line 12, FIG. 1, hereinafter referred to as Patent Document 1).

### SUMMARY OF THE INVENTION

Carbon nanotube has a high thermal conductivity, is stable to pure water, and is superhydrophobic to pure water. Meanwhile, as a working fluid in a heat transport device, pure water having a large latent heat is generally used. In a case of using pure water as a working fluid of the heat transport device having a carbon nanotube layer of Patent Document 1, the carbon nanotube layer may exhibit an extremely small capillary force because of the superhydrophobicity. Reflux of working fluid may thus be hindered. Further, a contact area of the carbon nanotube layer and the working fluid becomes smaller. Evaporation efficiency and condensation efficiency may thus be decreased.

In view of the above-mentioned circumstances, it is desirable to provide a heat transport device realizing a higher heat transport efficiency without being made larger, and an electronic apparatus including the heat transport device. It is further desirable to provide a heat transport device manufacturing method that realizes easier manufacture with higher reliability.

According to an embodiment of the present invention, there is provided a heat transport device including a working fluid, an evaporation portion, a condenser portion, a flow path portion, and an area. The working fluid includes pure water and an organic compound bearing a hydroxyl group. The evaporation portion causes the working fluid to evaporate from a liquid phase to a vapor phase. The condenser portion communicates with the evaporation portion, and causes the working fluid to condense from the vapor phase to the liquid phase. The flow path portion causes the working fluid condensed in the condenser portion to the liquid phase to flow to the evaporation portion. The area is made of a carbon material and provided on at least one of the evaporation portion, the condenser portion, and the flow path portion.

According to this embodiment, a water solution prepared by adding an organic compound bearing a hydroxyl group to pure water is used as the working fluid. As a result, hydrophilicity of the carbon material to the working fluid is improved. By improving hydrophilicity, capillary force in the carbon material is improved. Therefore, evaporation, condensation, and flow of the working fluid in the area made of the carbon material are accelerated. As a result, the heat transport device can transport heat efficiently.

According to the embodiment of the present invention, the organic compound bearing a hydroxyl group may be alcohol.

According to the embodiment of the present invention, the alcohol may be butanol, and a content of the butanol may be more than 2 wt % and 10 wt % or less.

Preferably, the content of the butanol is 2.1 wt % or more and 10 wt % or less. More preferably, the content of the butanol is 3 wt % or more and 10 wt % or less.

According to this embodiment, the working fluid including pure water and alcohol is used. By adding a small amount of butanol to pure water to prepare the working fluid, hydrophilicity and the capillary force are improved, and evaporation, condensation, and flow of the working fluid in the area made of the carbon material are accelerated.

According to the embodiment of the present invention, the carbon material may be carbon nanotube.

According to this embodiment, carbon nanotube has a nanostructure on the surface. So, the area having a large surface area is provided on at least one of the evaporation portion, the condenser portion, and the flow path portion. Accordingly, evaporation, condensation, and flow of the working fluid are accelerated while the heat transport device is not made larger. As a result, the heat transport device can transport heat efficiently.

According to the embodiment of the present invention, the area may be made of ultraviolet-treated carbon nanotube.

According to this embodiment, the area made of carbon nanotube is ultraviolet-treated, and hydrophilicity of the carbon nanotube to the working fluid is further improved. Accordingly, the capillary force in the carbon material is improved, and evaporation, condensation, and flow of the working fluid in the area made of the carbon material are further improved. As a result, the heat transport device can transport heat more efficiently.

According to the embodiment of the present invention, the area may have a groove on a surface thereof.

According to this embodiment, the groove on the surface improves the capillary force of the working fluid in the area. The flow of the working fluid is thus further accelerated. Further, by providing the groove on the surface, the area having a larger surface area can be provided on at least one of the evaporation portion, the condenser portion, and the flow path portion. Accordingly, evaporation, condensation, and flow of the working fluid are accelerated while the heat transport device is not made larger. As a result, the heat transport device can transport heat more efficiently.

According to the embodiment of the present invention, the alcohol may be ethanol, and a content of the ethanol may be 15 wt % or more and 40 wt % or less.

According to an embodiment of the present invention, there is provided an electronic apparatus including a heat source and a heat transport device thermally connected to the heat source. The heat transport device includes a working fluid, an evaporation portion, a condenser portion, a flow path portion, and an area. The working fluid includes pure water and an organic compound bearing a hydroxyl group. The evaporation portion causes the working fluid to evaporate from a liquid phase to a vapor phase. The condenser portion communicates with the evaporation portion, and causes the working fluid to condense from the vapor phase to the liquid phase. The flow path portion causes the working fluid condensed in the condenser portion to the liquid phase to flow to the evaporation portion. The area is made of a carbon material and provided on at least one of the evaporation portion, the condenser portion, and the flow path portion.

According to this embodiment, a water solution prepared by adding an organic compound bearing a hydroxyl group to pure water is used as the working fluid. As a result, hydrophilicity of the carbon material to the working fluid is improved. By improving hydrophilicity, capillary force in the carbon material is improved. Therefore, evaporation, condensation, and flow of the working fluid in the area made of the carbon material are accelerated. As a result, the heat transport device can transport heat efficiently.

According to an embodiment of the present invention, there is provided a manufacturing method of a heat transport device including an evaporation portion causing a working fluid to evaporate from a liquid phase to a vapor phase, a condenser portion causing the working fluid to condense from the vapor phase to the liquid phase, and a flow path portion causing the working fluid in the liquid phase to flow to the evaporation portion. An area made of a carbon material is formed on a first base member to obtain a second base member for at least one of the evaporation portion, the condenser portion, and the flow path portion. A container is formed with at least the second base member. A working fluid including pure water and an organic compound bearing a hydroxyl group is introduced to the container and sealing the container.

According to this embodiment, a water solution prepared by adding an organic compound bearing a hydroxyl group to pure water is used as the working fluid. As a result, hydrophilicity of the area made of the carbon material to the working fluid is improved.

The manufacturing method thus realizes easier manufacture with higher reliability.

By improving hydrophilicity as described above, capillary force in the carbon material is improved. Therefore, evaporation, condensation, and flow of the working fluid in the area made of the carbon material are accelerated. As a result, the heat transport device made by the manufacturing method can transport heat efficiently.

According to the embodiment of the present invention, the carbon material may be carbon nanotube, and the carbon nanotube may be ultraviolet-treated.

According to this embodiment, the carbon nanotube is ultraviolet-treated, and hydrophilicity of the area to the working fluid is further improved. By improving hydrophilicity as described above, the capillary force in the carbon material is improved, and evaporation, condensation, and flow of the working fluid in the area made of the carbon material are further improved. As a result, the heat transport device made by the manufacturing method can transport heat more efficiently.

As described above, according to the heat transport device of the embodiments of the present invention, by improving hydrophilicity of the carbon material to the working fluid, evaporation, condensation, and flow of the working fluid are improved. Accordingly, the heat transport device realizes a higher heat transport efficiency without being made larger. Further, the heat transport device manufacturing method of the embodiments of the present invention realizes easier manufacture with higher reliability.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a side view showing a heat spreader of an embodiment of the present invention, the heat spreader being thermally connected to a heat source;

FIG. 2 is a plan view showing the heat spreader;

FIG. 3 is a sectional view showing the heat spreader taken along the line A-A of FIG. 2;

FIG. 4 is a perspective view showing an evaporation portion;

FIG. 5 is a schematic diagram showing water repellency of carbon nanotube;

FIG. 6 is a diagram for explaining contact angles of alcohol water solution to a surface of carbon nanotube;

FIG. 7 is a table showing contact angles of refrigerants to ultraviolet-treated carbon nanotube;

FIG. 8 is a schematic diagram showing an operation of the heat spreader;

FIG. 9 is a flowchart showing a manufacturing method of the heat spreader;

FIGS. 10 are schematic diagrams showing in sequence an injection method of the refrigerant into a container;

FIG. 11 is a sectional view showing a heat pipe;

FIG. 12 is a schematic diagram showing an operation of the heat pipe; and

FIG. 13 is a perspective view showing a desktop PC as an electronic apparatus including the heat spreader.

### DESCRIPTION OF PREFERRED EMBODIMENTS

Hereinafter, embodiments of the present invention will be described with reference to the drawings.

In the following embodiments, description will be made while employing a heat spreader as a heat transport device.

(Structure of Heat Spreader)

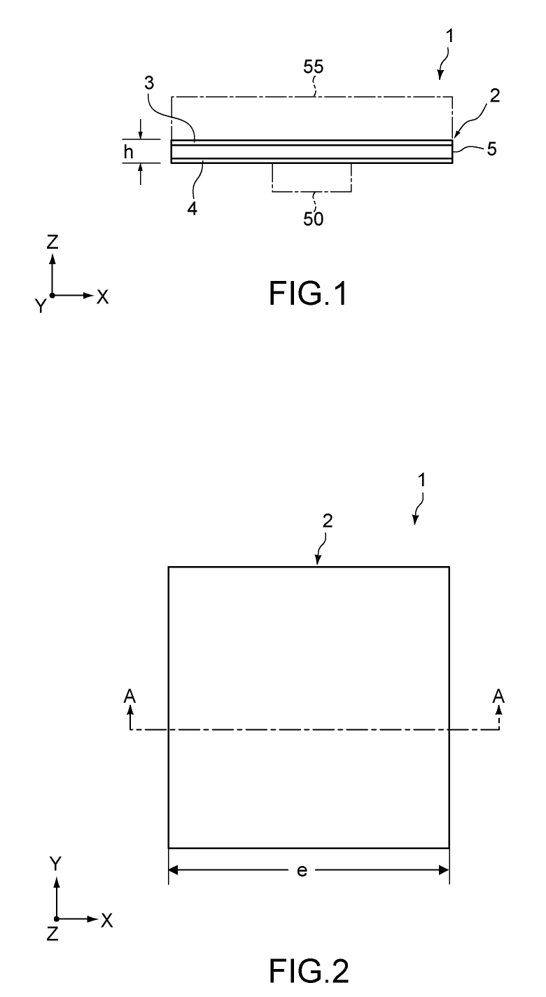

FIG. 1 is a side view showing a heat spreader of an embodiment of the present invention, the heat spreader being thermally connected to a heat source. FIG. 2 is a plan view showing the heat spreader of FIG. 1.

As shown in FIGS. 1-2, a heat spreader 1 includes a container 2. The container 2 includes a heat reception plate 4, a heat radiation plate 3, and sidewalls 5. The heat radiation plate 3 is provided so as to face the heat reception plate 4. The sidewalls 5 tightly bond the heat reception plate 4 and the heat radiation plate 3.

The heat radiation plate 3, the heat reception plate 4, and the sidewalls 5 may be bonded by brazing, that is, welded, or may be bonded with an adhesive material depending on the materials. The heat radiation plate 3, the heat reception plate 4, and the sidewalls 5 are made of a metal material, for example. The metal material is for example, copper having a high thermal conductivity, stainless steel, or aluminum, but not limited to the above. Other than the metal, a material having a high thermal conductivity such as carbon may be employed. All of the heat radiation plate 3, the heat reception plate 4, and the sidewalls 5 may be formed of different materials respectively, two of them may be formed of the same material, or all of them may be made of the same material.

The container 2 further includes a not-shown refrigerant (working fluid), sealed therein. The refrigerant will be described later.

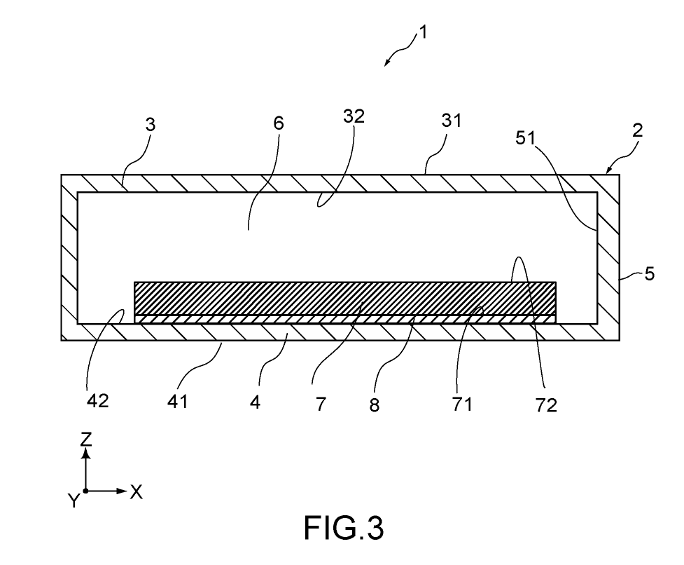

FIG. 3 is a sectional view showing the heat spreader 1 taken along the line A-A of FIG. 2.

The heat reception plate 4 includes a heat reception surface 41 and an evaporation surface 42 (evaporation portion). The heat reception surface 41 corresponds to an outer surface of the container 2. The evaporation surface 42 is a back surface of the heat reception surface 41, and faces the heat radiation plate 3.

A heat source 50 is thermally connected to the heat reception surface 41. The phrase “thermally connected” means, in addition to direct connection, connection via a thermal conductor, for example. The heat source 50 is, for example, an electronic component that generates heat such as a CPU (Central Processing Unit) or a resistor, or an electronic apparatus such as a display.

A base layer 8 is provided on the evaporation surface 42. The evaporation portion 7 is provided on the base layer 8. The evaporation portion 7 causes a not-shown liquid-phase refrigerant (hereinafter referred to as “liquid refrigerant”) to evaporate.

An inner space of the container 2 mainly serves as the flow path 6 for the liquid refrigerant and the vapor-phase refrigerant (hereinafter referred to as “vapor refrigerant”). That is, in the flow path 6, the liquid refrigerant flows from the heat radiation plate 3 side to the heat reception plate 4 side by gravity, and the vapor refrigerant flows from the heat reception plate 4 side to the heat radiation plate 3 side.

The heat radiation plate 3 includes a heat radiation surface 31 and a condenser surface 32 (condenser portion). The heat radiation surface 31 corresponds to an outer surface of the container 2. The condenser surface 32 is a back surface of the heat radiation surface 31, and faces the heat reception plate 4.

The condenser surface 32 causes the vapor refrigerant evaporated in the evaporation portion 7 to condense.

A heat radiation device such as a heat sink 55 is thermally connected to the heat radiation surface 31. Heat transmitted from the heat spreader 1 to the heat sink 55 is radiated from the heat sink 55.

Inner walls of the sidewalls 5 constitute a capillary flow path 51 (flow path portion). The capillary flow path 51 is a flow path for the liquid refrigerant condensed on the condenser surface 32 of the heat radiation plate 3. That is, in the capillary flow path 51, the liquid refrigerant flows from the heat radiation plate 3 side to the heat reception plate 4 side by a capillary force and gravity.

The evaporation portion 7 is made of a carbon material such as diamond, graphite, carbon nanotube, carbon nanofiber, or diamond-like carbon. In this embodiment, the evaporation portion 7 is made of carbon nanotube. The carbon nanotube has approximately 10 times higher thermal conductivity than copper, a typical metal material of a metal heat spreader, for example.

Accordingly, in a case where the evaporation portion 7 is made of carbon nanotube, extremely improved heat transfer efficiency is obtained compared to a heat spreader mainly made of a metal material.

Further, because carbon nanotube has a nanostructure and thus has a large specific surface area, extremely improved heat transfer efficiency is obtained compared to an evaporation portion having the same size as the evaporation portion 7 and being made of a metal material.

Note that in FIG. 3, for easier understanding, the shapes of the members are changed from the actual configuration. For example, the scale ratio of the evaporation portion 7 to the container 2 is made larger than the actual configuration. In FIG. 3, the evaporation portion 7 is provided on part of the heat reception surface 41, but may be provided on the entire surface of the heat reception surface 41.

The base layer 8 is a catalyst layer made of a metal material, for example, for forming the evaporation portion 7. The metal material is, for example, aluminum or titanium, but not limited to the above. In a case where the material of the heat radiation plate 3 may be a catalyst for the evaporation portion 7, the base layer 8 may not be prepared.

The heat spreader 1 of this embodiment is substantially square in a plan view. However, the shape of the heat spreader 1 is not limited to the above and may be an arbitrary shape. The heat spreader 1 has about 30-50 mm length (e) on each side, for example. The heat spreader 1 is substantially rectangular in the side view. The heat spreader 1 has about 2-5 mm height (h), for example. The heat spreader 1 having such a size is for a CPU of a PC (Personal Computer) as the heat source 50 thermally connected to the heat spreader 1. The size of the heat spreader 1 may be defined in accordance with the size of the heat source 50. For example, in a case where the heat source 50 thermally connected to the heat spreader 1 is a large-capacity heat source of a large-sized display or the like, the length e is needed to be made larger and may be as large as about 2600 mm. The size of the heat spreader 1 is defined such that the refrigerant can flow and condense appropriately, that is, the cycle of evaporation and condensation of the refrigerant flowing in the container 2 can be repeated smoothly. The operating temperature range of the heat spreader 1 is for example −40° C. to +200° C., approximately. The endothermic density of the heat spreader 1 is for example 8W/mm² or lower.

(Structure of Evaporation Portion)

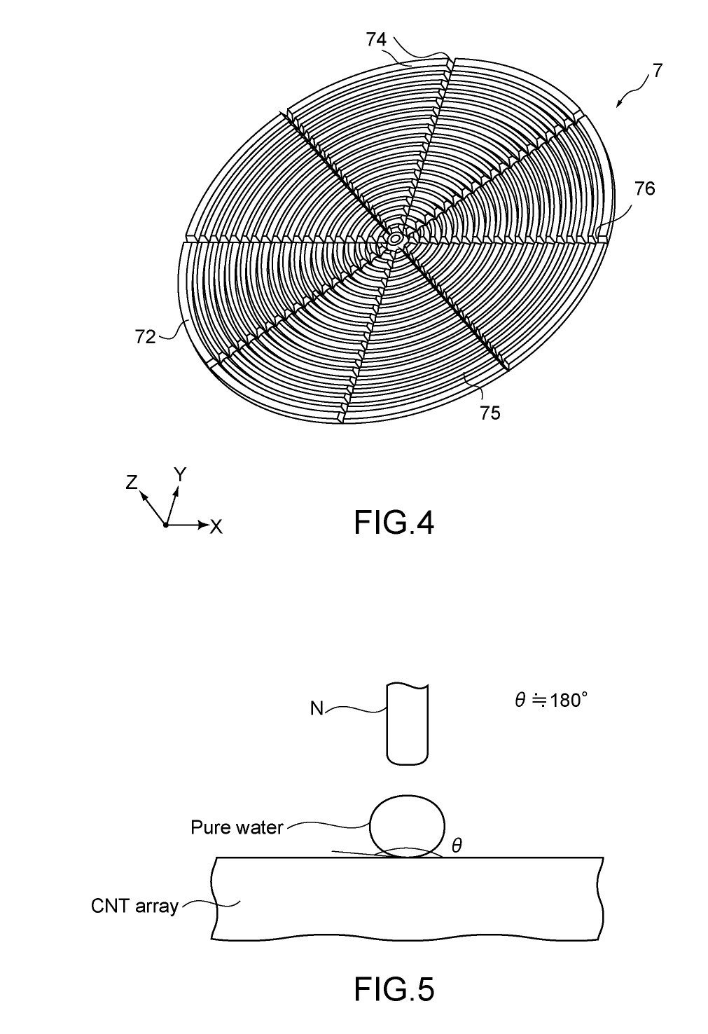

FIG. 4 is a perspective view showing the evaporation portion 7.

As shown in FIG. 4, the evaporation portion 7 is substantially circular in a plan view. The evaporation portion 7 includes an evaporation surface 72 and a heat reception surface 71. The evaporation surface 72 is a front surface of the evaporation portion 7. The heat reception surface 71 is a back surface of the evaporation portion 7. Grooves 74 are provided on the evaporation surface 72.

The grooves 74 include circumferential grooves 75 and diametrical grooves 76. The circumferential grooves 75 are numerous concentric circles formed at predetermined distances with a center point O of the evaporation surface 72 being a center. The diametrical grooves 76 are in a radial pattern passing through the center point O provided to the evaporation portion 7.

The arrangement of the grooves 74 is not limited to the above. The grooves 74 may be arbitrarily arranged as long as the refrigerant can flow in the entire grooves 74. For example, the circumferential grooves 75 may be concentric polygons, concentric ellipsoids, or a spiral with the center point O being a center. Alternatively, the grooves 74 may not be circular and diametrical, but may be in parallel or grid-like.

The grooves 74 of the above arrangement help the liquid refrigerant to flow on the entire evaporation surface 72 of the evaporation portion 7. Accordingly, the liquid refrigerant can efficiently flow by a capillary force.

The groove 74 has a V-shaped section or a U-shaped section, for example. Specifically, the groove 74 having a V-shaped section exhibits the following phenomenon. The liquid refrigerant in the groove 74 has a thin liquid film zone in the vicinity of a meniscus. The groove 74 having the V shape can ensure a large thin liquid film zone in the vicinity of the meniscus, compared to a U-shaped groove, for example. Heat from the evaporation portion 7 is transferred to the liquid refrigerant with higher thermal conductivity in the thin liquid film zone than that in an area other than the thin liquid film zone. So, evaporation efficiency of the liquid refrigerant in the thin liquid film zone is higher than evaporation efficiency in the area other than the thin liquid film zone. Accordingly, the V-shaped groove 74 that can ensure the large thin liquid film zone realizes higher thermal conductivity and evaporation efficiency than those of a U-shaped groove.

The evaporation portion 7 is substantially circular in a plan view and is provided at a substantially center portion of the evaporation surface 42 of the heat reception plate 4, but not limited to the above. The shape of the evaporation portion 7 in a plan view may be substantially ellipsoidal or polygonal, or another arbitrary shape. The diameter of the evaporation portion 7 is about 30 mm, for example, but not limited to the above. The thickness of the evaporation portion 7 is, for example, 10-50 μm, typically about 20 μm. The size of the evaporation portion 7 is arbitrarily changed according to the amount of heat generated by the heat source 50. The mount area of the evaporation portion 7 on the evaporation surface 42 of the heat reception plate 4 is not limited to the substantially center thereof. The evaporation portion 7 may be provided on another arbitrary area. The scale ratio of the evaporation portion 7 to the evaporation surface 42 of the heat reception plate 4 is not limited to that shown in the drawings, and is arbitrarily changed. In FIG. 4, for easier understanding, the scale ratio of the grooves 74 to the evaporation portion 7 is changed from the actual configuration.

(Composition of Refrigerant)

Next, the refrigerant sealed in the container 2 of the heat spreader 1 will be described.

FIG. 5 is a schematic diagram showing water repellency of carbon nanotube.

As shown in FIG. 5, a carbon material such as carbon nanotube constituting the evaporation portion 7 is stable to pure water, has higher thermal conductivity, is superhydrophobic to pure water, and has a contact angle as large as approximately 180°. Meanwhile, pure water is generally used as a refrigerant for a heat spreader. There is a fear that in a case where the evaporation portion 7 is made of carbon nanotube and pure water is used as a refrigerant in the heat spreader 1, evaporation efficiency and condensation efficiency of the heat spreader 1 may be decreased because of the superhydrophobicity of carbon nanotube.

Further, there is a fear that the superhydrophobicity may hinder the capillary force in the evaporation portion 7 and reflux of the refrigerant. Note that the capillary force is obtained by the following expression (1).

ΔP=2δ cos θ/r (1)

Here, ΔP represents capillary force, δ represents surface tension of working fluid, θ represents contact angle, and r represents representative length. Representative length r corresponds to a diameter of the capillary.

According to the expression (1), to increase capillary force ΔP, surface tension δ is increased, contact angle θ is decreased, and representative length r is decreased.

A refrigerant is prepared by adding a small amount of an organic compound bearing a hydroxyl group (OH group) to pure water. The contact angle θ of the refrigerant to the carbon material such as carbon nanotube is thus made smaller. That is, hydrophilicity is improved, and capillary force ΔP is increased enough.

Specific examples of the organic compound bearing a hydroxyl group added to pure water include alcohols such as methanol, ethanol, propanol, butanol, and hexanol, diols such as ethylene glycol and propylene glycol, polyols such as glycerin, and phenols such as phenol and alkylphenol.

More specifically, in a case of using higher alcohol of carbon number 4 or more as alcohols, it is known that surface tension of refrigerant is improved as temperature increases. This phenomenon compensates for evaporation of a working fluid in a portion having a higher temperature, and is called self-rewetting. The self-rewetting phenomenon prevents dryout and improves the property of the heat spreader 1. So, by using carbon nanotube as the evaporation portion 7 and the refrigerant prepared by adding the alcohols to pure water, wetting ability is improved and also the self-rewetting phenomenon is exhibited synergistically, to thereby improve capillary force.

(Addition of Ethanol or Butanol to Pure Water)

As specific examples of the organic compound bearing a hydroxyl group added to pure water, ethanol and butanol are respectively added to pure water to prepare alcohol water solutions. Contact angle measurement experiment of those alcohol water solutions will be described.

Alcohol water solution as refrigerant was dropped on a vertically-aligned carbon nanotube array, and a contact angle of the alcohol water solution to the carbon nanotube was measured. Ethanol and butanol were used as alcohol. A ball of the alcohol water solution was formed on a tip of a Teflon®-coated needle N. The ball of the alcohol water solution was caused to contact a surface of the carbon nanotube, and the needle N was lifted. A liquid drop thus remained on the surface of the carbon nanotube, and the contact angle was measured.

The amount of ethanol added to pure water was 10 wt %, 20 wt %, and 30 wt %. The amount of butanol added to pure water was 1 wt %, 2 wt %, 3 wt %, and 5 wt %.

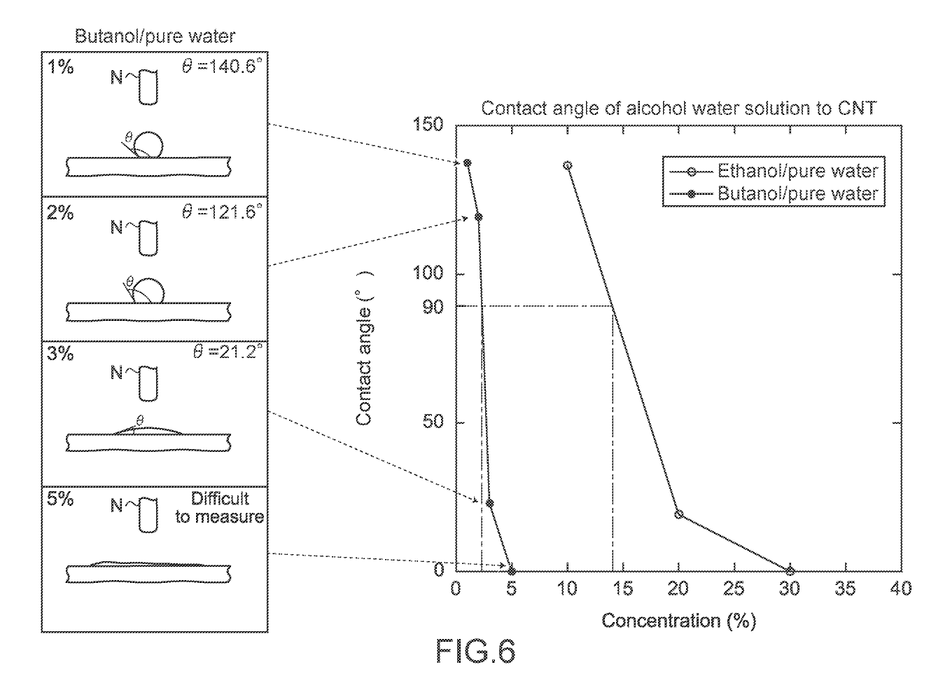

FIG. 6 is a diagram showing measurement results of contact angles of alcohol water solution to the surface of the carbon nanotube.

As shown in FIG. 6, in the case of adding 10 wt % of ethanol to pure water, a liquid drop remained on the surface of the carbon nanotube. In the case of adding 20 wt % of ethanol to pure water, the contact angle was decreased largely. In the case of adding 30 wt % of ethanol to pure water, the liquid drop spread completely such that it was difficult to measure a contact angle to thereby exhibit enough wetting ability.

Meanwhile, in the case of adding 1 wt % of butanol to pure water, a liquid drop remained on the surface of the carbon nanotube. In the case of adding 3 wt % of butanol to pure water, the contact angle was decreased largely. In the case of adding 5 wt % of butanol to pure water, the liquid drop spread completely. More specifically, in the case of adding 1 wt % of butanol to pure water, the contact angle θ was 140.6°. In the case of adding 2 wt % of butanol to pure water, the contact angle θ was 121.6°. In the case of adding 3 wt % of butanol to pure water, the contact angle θ was 21.2°. In the case of adding 5 wt % of butanol to pure water, it was difficult to measure a contact angle to thereby exhibit enough wetting ability. As described above, by adding much smaller amount of butanol than ethanol, wetting ability to carbon nanotube is extremely improved.

Minimum requirement to reflux the working fluid by the capillary force is satisfaction of ΔP>0 in the above expression (1), that is, satisfaction of 090°. To satisfy θ(contact angle)≦90° and to reflux the working fluid by the capillary force, the content of the butanol is more than 2 wt % as shown in the graph. Preferably, the content of the butanol is 2.1 wt % or more. More preferably, the content of the butanol is 3 wt % or more.

To satisfy θ(contact angle)≦90° and to reflux the working fluid by the capillary force, the content of ethanol is larger than about 15 wt %.

Note that in a case where wt % of butanol or ethanol increases, surface tension along with the increase largely decreases to thereby affect the capillary force adversely. In view of the above, the added amount of butanol is about 10 wt % or less, and the added amount of ethanol is about 40 wt % or less.

As described above, the smaller contact angle of the refrigerant to the carbon nanotube improves the capillary force and evaporation efficiency of the liquid refrigerant.

(Reform of Surface of Evaporation Portion)

With the use of the refrigerant prepared by adding butanol or ethanol to pure water, the surface of the evaporation portion 7 may be reformed to improve the capillary force. The surface is reformed by, for example, introduction of hydrophilic group such as carboxyl (COOH) group with ultraviolet treatment.

For example, the ultraviolet treatment is performed as follows. An excimer lamp (light intensity of lamp tube surface is 50 mW/cm², for example) of wavelength 172 nm is prepared. A vertically-aligned carbon nanotube array is arranged 2 mm below the tube surface. The surface of the evaporation portion 7 is irradiated with ultraviolet in the atmosphere to reform the surface. The irradiation time is about 1 minute, for example. With the ultraviolet treatment, active oxygen or ozone is generated from oxygen in the atmosphere to oxidize the carbon nanotube. Hydrophilic group such as carboxyl (COOH) group having hydrophilicity is thus formed on the surface of the evaporation portion 7.

Water solution of, for example, 1 wt % butanol water solution was dropped on the surface-reformed carbon nanotube by using the needle N, and the contact angle was measured.

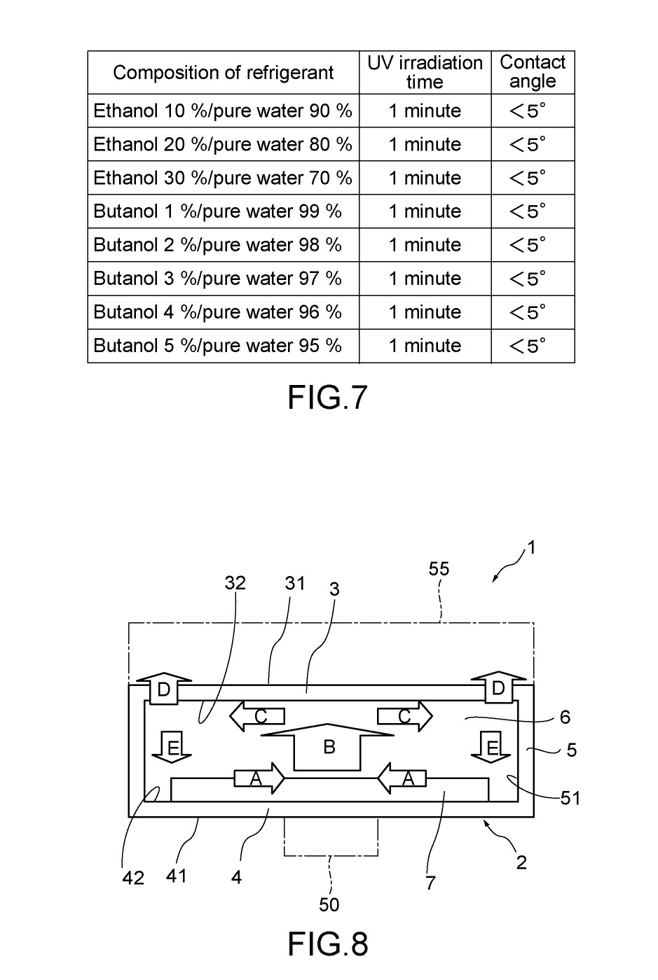

FIG. 7 is a table showing contact angles of refrigerants to ultraviolet-treated carbon nanotube.

Contact angle θ of 1 wt % butanol water solution to carbon nanotube before the ultraviolet-treatment is 140.6°. Carbon nanotube subjected to ultraviolet irradiation of about 1 minute realizes the contact angle as small as less than 5° to thereby improve the capillary force compared to the carbon nanotube before the ultraviolet-treatment. Further, even in a case of variously changing compositions of the refrigerant as shown in FIG. 7, carbon materials subjected to ultraviolet irradiation of about 1 minute realize smaller contact angles to thereby improve hydrophilicity and the capillary force irrespective of compositions of the refrigerant.

Note that in this embodiment, the refrigerant is prepared by adding butanol or ethanol to pure water. In a case of using pure water as the refrigerant, the ultraviolet-treated carbon nanotube makes the contact angle smaller and improves the capillary force.

(Operation of Heat Spreader)

The operation of the heat spreader 1 as structured above will be described.

FIG. 8 is a schematic diagram showing the operation of the heat spreader 1.

When the heat source 50 generates heat, the heat reception surface 41 of the heat reception plate 4 receives the heat. Then, the liquid refrigerant flows by the capillary force in the grooves 74 of the evaporation portion 7 provided on the evaporation surface 42, which is a back surface of the heat reception surface 41 (arrow A). The liquid refrigerant evaporates mainly from the evaporation surface 72 of the evaporation portion 7 to be the vapor refrigerant. Some of the vapor refrigerant flows in the grooves 74 of the evaporation portion 7, but most of the vapor refrigerant flows in the flow path 6 to the heat radiation plate 3 side (arrow B). As the vapor refrigerant flows in the flow path 6, the heat diffuses, and the vapor refrigerant condenses on the condenser surface 32 of the heat radiation plate 3 to be the liquid phase (arrow C). Thus, the heat diffused by the heat spreader 1 is transferred from the heat radiation surface 31, which is a back surface of the condenser surface 32, to the heat sink 55. The heat sink 55 radiates the heat (arrow D). The liquid refrigerant flows in the capillary flow path 51 by the capillary force and in the flow path 6 by gravity to return to the heat reception side (arrow E). By repeating the above operation, the heat spreader 1 transports the heat of the heat source 50.

The operational zones as shown by the arrows A to E are merely rough guide or rough standard and not clearly defined since respective operational zones may be shifted according to the amount of heat generated by the heat source 50 or the like.

(Manufacturing Method of Heat Spreader)

A manufacturing method of the heat spreader 1 according to the embodiment will be described.

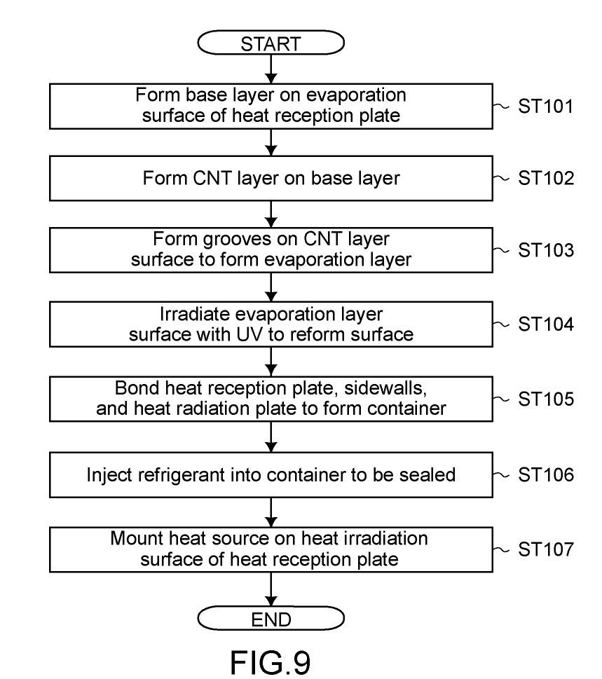

FIG. 9 is a flowchart showing the manufacturing method of the heat spreader 1.

The base layer 8 is formed on the evaporation surface 42 of the heat reception plate 4 (Step 101).

The base layer 8 is a catalyst layer on which carbon nanotube is produced.

Next, carbon nanotube is densely produced on the base layer 8 to form a carbon nanotube layer (Step 102).

The carbon nanotube may be produced on the catalyst layer by plasma CVD (Chemical Vapor Deposition) or thermal CVD, but not limited to the above. The evaporation surface 42 may be reformed by the above-mentioned ultraviolet treatment. The condenser surface 32 of the heat radiation plate 3 may also be reformed by the ultraviolet treatment.

Next, the V-shaped grooves are formed on the surface of the carbon nanotube layer with a processing tool (turning tool) (Step 103). The evaporation portion 7 having the grooves 74 on the evaporation surface 72 is thus formed. In general, it is difficult to form a minute structure by machine-processing carbon nanotube having a micrometer-order structure, and such a minute structure is usually formed by etching. To the contrary, from the perspective of the inventors of the present invention, the densely-grown carbon nanotube is treated as a single material (carbon nanotube layer). By minutely bending the carbon nanotube, a micrometer-order structure is formed. This processing method is easier than cutting a substrate made of, for example, a metal material, the cost thereof is lower than the cost of the etching, and a preferable minute processability is realized. The turning tool may be made of a material lower in hardness than the metal material of the base layer 8. In this case, the base layer 8, the heat reception plate 4, and the turning tool itself are not scratched when processing. Further, it is possible to keep the distance from the base layer 8 to the bottom portion 77 of the groove 74 1 μm or more. The evaporation portion 7 is thus free from scratch or separation. There is no fear that the refrigerant flows through the damaged base layer 8 between the heat reception plate 4 and the base layer 8 and that the entire base layer 8 is peeled.

Alternatively, the grooves 74 may be formed by press molding using a die. Also in this case, the die may be made of a material lower in hardness than the metal material of the base layer 8 to the same effect.

Alternatively, the evaporation portion 7 having the grooves 74 on the surface may be formed by causing a reactive gas to flow between a die having precisely-processed, desired V-shaped grooves and the heat reception plate 4 having the evaporation surface 42 provided with the base layer 8 as a catalyst layer. In this method, it is not necessary to perform cutting or the like, so the fear of scratching the base layer 8 and the heat reception plate 4 is further decreased. Note that this method is performed only in the thermal CVD.

Alternatively, the V-shaped grooves may be formed on the evaporation surface 42 of the heat reception plate 4, the base layer 8 as a catalyst layer having the corresponding V-shaped grooves may be formed on the heat reception plate 4, and a carbon nanotube layer having the corresponding V-shaped grooves may be formed on the base layer 8. Also in this method, it is not necessary to perform cutting or the like, so the fear of scratching the base layer 8 and the heat reception plate 4 is further decreased.

Next, the evaporation surface 72 of the evaporation portion 7 is reformed with the ultraviolet treatment as described above (Step 104) as appropriate.

Next, the heat reception plate 4, the sidewalls 5, and the heat radiation plate 3 are bonded to form the container 2 (Step 105). In the bonding, the respective members are precisely aligned.

Next, the refrigerant is injected into the container 2 and the container 2 is sealed (Step 106). As described above, the refrigerant is prepared by adding a predetermined amount of an organic compound bearing a hydroxyl group (OH group) to pure water.

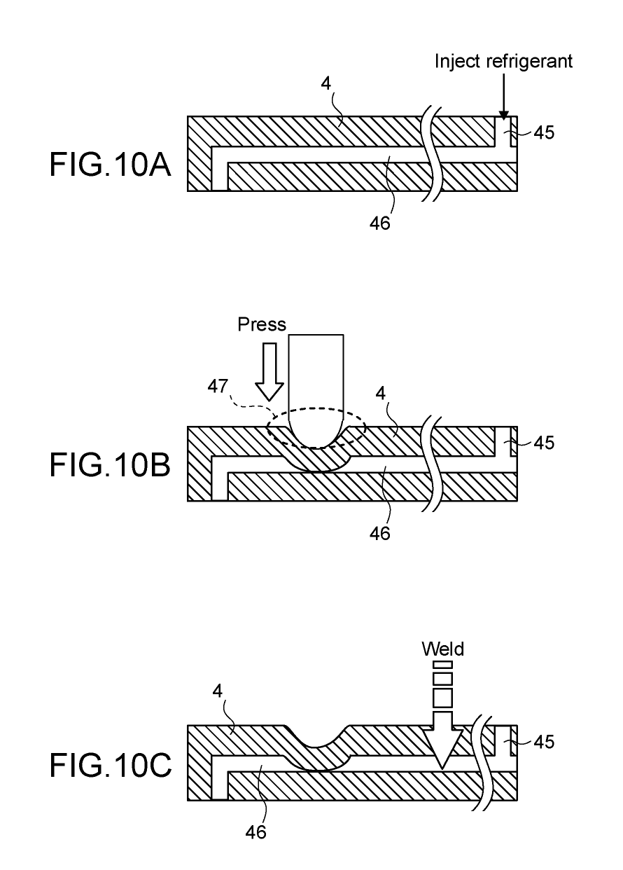

FIGS. 10 are schematic diagrams showing in sequence the injection method of the refrigerant into the container 2.

The heat reception plate 4 includes an injection port 45 and an injection path 46.

As shown in FIG. 10A, the pressure of the flow path 6 is decreased via the injection port 45 and the injection path 46, for example, and the refrigerant is injected into an inner flow path from a dispenser (not shown) via the injection port 45 and the injection path 46.

As shown in FIG. 10B, a press area 47 is pressed and the injection path 46 is closed (temporal sealing). The pressure of the flow path 6 is decreased via another injection path 46 and another injection port 45, and when the pressure of the flow path 6 reaches a target pressure, the press area 47 is pressed and the injection path 46 is closed (temporal sealing).

As shown in FIG. 10C, on a side closer to the injection port 45 than the press area 47, the injection path 46 is closed by laser welding for example (final sealing). Accordingly, the inner space of the heat spreader 1 is sealed tightly. By injecting the refrigerant into the container 2 and sealing the container 2 as described above, the heat spreader 1 is manufactured.

Next, the heat source 50 is mounted on the heat reception surface 41 of the heat reception plate 4 (Step 107). In a case where the heat source 50 is a CPU, the process is for example a reflow soldering processing.

The reflow processing and the manufacturing processing of the heat spreader 1 may be executed in different areas (for example different factories). So, in the case of executing the injection of the refrigerant after the reflow processing, it is necessary to transport the heat spreader 1 to and from the factories, which leads to problems of cost, manpower, time, or generation of particles of the transfer between factories. According to this manufacturing method, it is possible to execute the reflow processing after the completion of the heat spreader 1, solving the above problem.

Next, heat transport devices according to other embodiments of the preset invention will be described.

(Condenser Portion of Another Embodiment)

In the above embodiment, the evaporation portion 7 made of a carbon material such as carbon nanotube is provided on the evaporation surface 42 of the heat reception plate 4, but is not limited the above. Alternatively, a condenser portion made of a carbon material may be provided on the entire surface or part of the condenser surface 32 of the heat radiation plate 3. Grooves may be provided on the surface of the condenser portion. Examples of the carbon material include carbon nanotube.

Carbon nanotube has higher thermal conductivity and has a nanostructure on the surface. Accordingly, compared to the condenser surface 32 only formed of the heat radiation plate 3 made of metal material or the like, condensation and heat radiation are actively performed. Further, the nanostructure and the grooves provided on the condenser portion improve the capillary force. Accordingly, flow and condensation of the liquid refrigerant on the condenser surface are further improved, and heat radiation is further improved.

Carbon nanotube of the condenser portion may be formed such that the tip portions face downward. The liquid refrigerant flows on the carbon nanotube having the tip portions facing downward by gravity to the evaporation surface 42 of the heat reception plate 4. With this structure, flow of the liquid refrigerant is accelerated. Further, condensation of the vapor refrigerant newly reaching the condenser layer is not hindered. Accordingly, a supply amount of the liquid refrigerant to the condenser surface 32 is not likely to be decreased, reflux of the refrigerant is not hindered, and stable operation is realized.

Alternatively, the evaporation portion 7 made of the carbon material is not provided on the evaporation surface 42 of the heat reception plate 4. According to another embodiment of the present invention, a condenser layer made of a carbon material may be provided only on the condenser surface 32 of the heat radiation plate 3.

(Heat Transport Device of Another Embodiment)

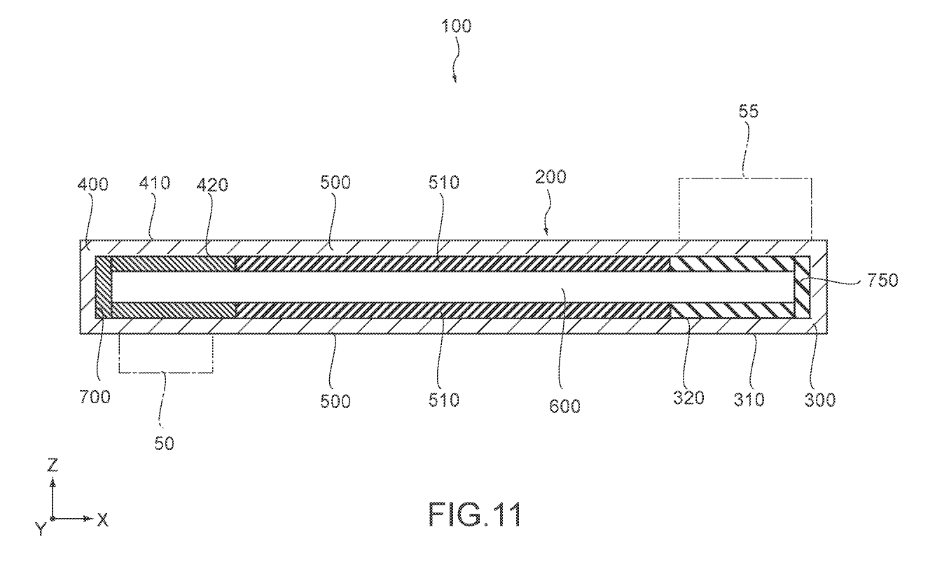

FIG. 11 is a sectional view showing a heat pipe as a heat transport device according to another embodiment of the present invention.

As shown in FIG. 11, a heat pipe 100 includes a pipe-like container 200. The container 200 includes a heat reception side end portion 400, a heat radiation side end portion 300, and a wall portion 500. The heat reception side end portion 400 is provided on an end portion of the container 200. The heat radiation side end portion 300 is provided on the other end portion of the container 200 so as to face the heat reception side end portion 400. The wall portion 500 couples the heat reception side end portion 400 and the heat radiation side end portion 300.

An inner space of the container 200 mainly constitutes a flow path 600 for a refrigerant (working fluid). The container 200 further includes a refrigerant, sealed therein. The refrigerant is prepared by adding a predetermined amount of an organic compound bearing a hydroxyl group (OH group) to pure water.

On an inner surface (flow path portion) of the wall portion 500, a capillary flow path 510 (area) is provided such that the capillary flow path 510 couples the heat reception side end portion 400 and the heat radiation side end portion 300. The capillary flow path 510 is made of a carbon material such as carbon nanotube. On the capillary flow path 510, linear grooves may be provided such that the linear grooves couple the heat reception side end portion 400 and the heat radiation side end portion 300.

The heat reception side end portion 400 includes a heat reception surface 410 and an evaporation surface 420 (evaporation portion). The heat reception surface 410 corresponds to an outer surface of the container 200. The evaporation surface 420 faces the heat radiation side end portion 300. On the evaporation surface 420, an evaporation portion 700 (area) is provided. The evaporation portion 700 is made of a carbon material such as carbon nanotube, and has grooves on the surface. The evaporation portion 700 may be provided on the entire surface or part of the evaporation surface 420.

The heat radiation side end portion 300 includes a heat radiation surface 310 and a condenser surface 320 (condenser portion). The heat radiation surface 310 corresponds to an outer surface of the container 200. The condenser surface 320 faces the heat reception side end portion 400. On the condenser surface 320, a condenser layer 750 (area) is provided. The condenser layer 750 is made of a carbon material such as carbon nanotube, and has grooves on the surface. The condenser layer 750 may be provided on the entire surface or part of the condenser surface 320.

Surfaces of the capillary flow path 510, the evaporation surface 420, the evaporation portion 700, the condenser surface 320, and the condenser layer 750 may be ultraviolet-treated and reformed. The evaporation portion 700 and the condenser layer 750 may be provided on the capillary flow path 510 in an integral manner. Alternatively, the evaporation portion 700 and the condenser layer 750 may be provided separately. All of the capillary flow path 510, the evaporation portion 700, and the condenser layer 750 may not necessarily be provided. At least one of them may be provided.

A heat source 50 is thermally connected to the heat reception surface 410 of the heat reception side end portion 400 of the container 200. A heat sink 55 is thermally connected to the heat radiation surface 310 of the heat radiation side end portion 300.

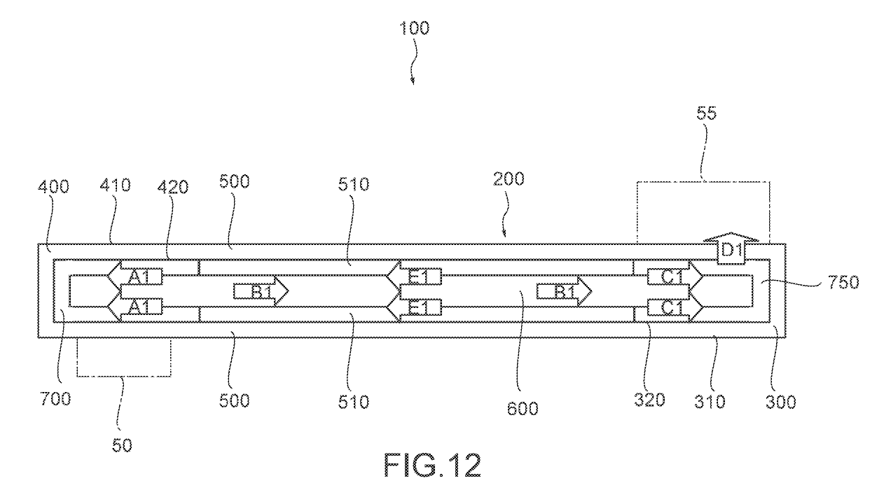

FIG. 12 is a schematic diagram showing the operation of the heat pipe 100.

When the heat source 50 generates heat, the heat reception surface 410 of the heat reception side end portion 400 receives the heat, as shown in FIG. 12. Then, the liquid refrigerant flows by the capillary force in the grooves of the evaporation portion 700 provided on the evaporation surface 420 of the heat reception side end portion 400 (arrow A1). The liquid refrigerant evaporates from the evaporation surface of the evaporation portion 700 provided on the heat reception side end portion 400 to be the vapor refrigerant. Some of the vapor refrigerant flows in the grooves of the evaporation portion 700, but most of the vapor refrigerant flows in the flow path 600 to the heat radiation side end portion 300 side by a slight pressure difference (arrow B1). As the vapor refrigerant flows in the flow path 600, the heat diffuses, and the vapor refrigerant condenses on the condenser layer 750 provided on the condenser surface 320 of the heat radiation side end portion 300 to be the liquid phase (arrow C1). Thus, the heat diffused by the heat pipe 100 is transferred from the heat radiation surface 310 of the heat radiation side end portion 300 to the heat sink 55. The heat sink 55 radiates the heat (arrow D1). The liquid refrigerant flows in the capillary flow path 510 by the capillary action to return to the heat reception side end portion 400 (arrow E1). By repeating the above operation, the heat pipe 100 transports the heat of the heat source 50.

According to the heat pipe 100, the refrigerant that is prepared by adding a predetermined amount of an organic compound bearing a hydroxyl group (OH group) to pure water flows in the capillary flow path 510 made of the carbon material and having the grooves. Accordingly, this realizes an improved capillary force and improved reflux of the refrigerant.

(Electronic Apparatus)

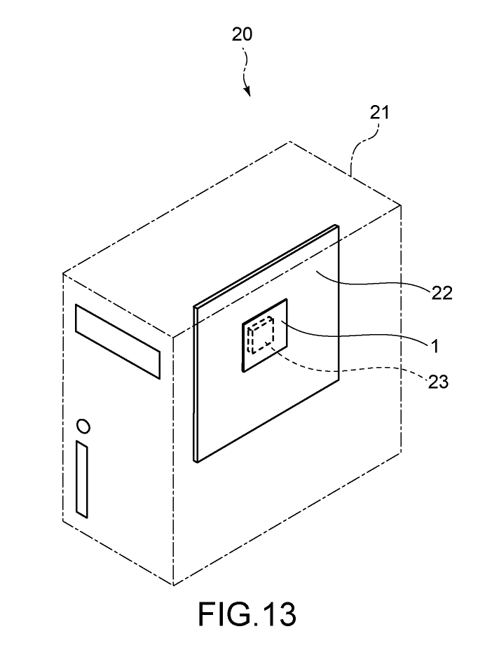

FIG. 13 is a perspective view showing a desktop PC as an electronic apparatus including the heat spreader 1.

In a case 21 of a PC 20, a circuit board 22 is provided, and a CPU 23 for example is mounted on the circuit board 22. The CPU 23 as a heat source is thermally connected to the heat spreader 1, and the heat spreader 1 is thermally connected to a heat sink.

The embodiments according to the present invention are not limited to the embodiments described above, and various modifications are conceivable.

For example, the evaporation portion 7 is provided on part of the heat reception plate 4, but not limited to the above. An evaporation layer made of a carbon material may be provided as the evaporation portion 7 on the entire surface of the heat reception plate 4.

As a heat transport device, the heat spreader and the heat pipe are exemplarily shown. However, the heat transport device is not limited to the above, but may be a CPL.

The shape of the heat spreader 1 is rectangular or square in a plan view. However, the shape in a plan view may be circular, ellipsoidal, polygonal, or another arbitrary shape.

As an electronic apparatus, the desktop PC is exemplarily shown, but not limited to the above. As an electronic apparatus, a PDA (Personal Digital Assistance), an electronic dictionary, a camera, a display apparatus, an audio/visual apparatus, a projector, a mobile phone, a game apparatus, a car navigation apparatus, a robot apparatus, a laser generation apparatus, or another electronic appliance may be employed.

The present application contains subject matter related to that disclosed in Japanese Priority Patent Application JP 2009-091216 filed in the Japan Patent Office on Apr. 3, 2009, the entire content of which is hereby incorporated by reference.

What is claimed is:

1. A heat transport device, comprising:
a working fluid including pure water and an organic compound bearing a hydroxyl group;
an evaporation portion causing the working fluid to evaporate from a liquid phase to a vapor phase;
a condenser portion communicating with the evaporation portion and causing the working fluid to condense from the vapor phase to the liquid phase;
a flow path portion causing the working fluid condensed in the condenser portion to the liquid phase to flow to the evaporation portion; and
an area made of a carbon material and provided on at least one of the evaporation portion, the condenser portion, and the flow path portion.

2. The heat transport device according to claim 1,
wherein the organic compound bearing a hydroxyl group is alcohol.

3. The heat transport device according to claim 2,
wherein the alcohol is butanol, and a content of the butanol is more than 2 wt % and 10 wt % or less.

4. The heat transport device according to claim 3,
wherein the carbon material is carbon nanotube.

5. The heat transport device according to claim 4,
wherein the area is made of ultraviolet-treated carbon nanotube.

6. The heat transport device according to claim 5,
wherein the area has a groove on a surface thereof.

7. The heat transport device according to claim 2,
wherein the alcohol is ethanol, and a content of the ethanol is 15 wt % or more and 40 wt % or less.

8. An electronic apparatus, comprising:
a heat source; and
a heat transport device thermally connected to the heat source, the heat transport device including a working fluid including pure water and an organic compound bearing a hydroxyl group, an evaporation portion causing the working fluid to evaporate from a liquid phase to a vapor phase, a condenser portion communicating with the evaporation portion and causing the working fluid to condense from the vapor phase to the liquid phase, a flow path portion causing the working fluid condensed in the condenser portion to the liquid phase to flow to the evaporation portion, and an area made of a carbon material and provided on at least one of the evaporation portion, the condenser portion, and the flow path portion.

9. A manufacturing method of a heat transport device including an evaporation portion causing a working fluid to evaporate from a liquid phase to a vapor phase, a condenser portion causing the working fluid to condense from the vapor phase to the liquid phase, and a flow path portion causing the working fluid in the liquid phase to flow to the evaporation portion, comprising:
forming an area made of a carbon material on a first base member to obtain a second base member for at least one of the evaporation portion, the condenser portion, and the flow path portion;
forming a container with at least the second base member; and
introducing a working fluid including pure water and an organic compound bearing a hydroxyl group to the container and sealing the container.

10. The manufacturing method of a heat transport device according to claim 9,
wherein the carbon material is carbon nanotube, and the carbon nanotube is ultraviolet-treated.
